(19) United States
(12) Patent Application Publication
(10) Pub. No.: US 2012/0187433 A1
(43) Pub. Date: Jul. 26, 2012

(54) STRUCTURE OF LIGHT SOURCE MODULE AND MANUFACTURING METHOD THEREOF

(75) Inventors: Min-Hua CHEN, Taipei (TW); Chao-Yi Chen, Taipei (TW); Tzu-Pin Huan, Taipei (TW)

(73) Assignee: GETAC TECHNOLOGY CORPORATION, HSINCHU (TW)

(21) Appl. No.: 13/078,623

(22) Filed: Apr. 1, 2011

Related U.S. Application Data
(60) Provisional application No. 61/436,502, filed on Jan. 26, 2011.

(30) Foreign Application Priority Data
Mar. 9, 2011 (CN) CN201110065825.8

(51) Int. Cl. H01L 33/50; H01L 33/64

(52) U.S. Cl. 257/98; 438/27; 257/E33.056; 257/E33.061

(57) ABSTRACT

A circuit substrate and at least one light-emitting diode (LED) chip are adhered to a heatsink substrate in sequence, and then a packaging material is formed on the LED chip. The circuit substrate has at least one through hole, and the LED chip is buried in the through hole on the circuit substrate so that the LED chip is in direct contact with the heatsink substrate, so as to reduce the thermal resistance between the LED chip and the heatsink substrate, thus effectively dissipating the heat energy of the LED chip through the heatsink substrate.

### BACKGROUND OF THE INVENTION

1. Field of Invention

The present invention relates to a manufacturing method of a light source module and a structure thereof, and more particularly to a manufacturing method of a light-emitting diode (LED) used as a light source module and a structure thereof.

2. Related Art

In recent years, the application of LEDs has evolved from early low-power products (for example, signal indicators and key illuminators for mobile phones) to current high-power products (for example, lighting tubes, bulbs and street lamps). The amount of heat generated by the high-power LED per unit area (density of heat generation) is rather high, and even higher than that of an ordinary Integrated Circuit (IC) device, so that the junction temperature of the LED is dramatically increased. If the junction temperature is too high, the luminous efficiency of the LED is reduced (the brightness is reduced) and oxidation of the internal wiring is accelerated (the service life is reduced). Therefore, heat dissipation of the LED is the primary problem for the application of LEDs to high-power products.

An LED bulb is taken as an example. A conventional LED bulb mainly includes a circuit board (an aluminum substrate) and a heatsink lamp holder, in which, a printed circuit is disposed on the circuit board, LEDs are installed on the circuit board first, and then the circuit board is disposed on the heatsink lamp holder. As described above, the heat dissipation of the LED is the primary problem for high-power products all the time, and the simplest manner for solving the heat dissipation problem is to increase the heat-dissipation area. The LED bulb still needs to conform to the specifications (E14, E27) of conventional bulb screw bases, and thus the bulb can be installed on the conventional lamp holder for providing electric energy. Since the heatsink lamp holder of the LED bulb is limited to the conventional bulb specifications, the heat-dissipation area of the LED bulb cannot be increased without limitation. In order to effectively solve the heat dissipation problem of the LED bulb, a miniature fan is further added in the heatsink lamp holder in the prior art, and the miniature fan can provide forced convection to accelerate the heat exchange between the heatsink lamp holder and external cold air.

However, the circuit board of the conventional LED bulb is a thermal resistance between the LED and the heatsink lamp holder, and whether the circuit board is tightly adhered to the heatsink lamp holder also affects the heat transfer. Moreover, the LED used in the conventional LED bulb is manufactured through an independent process, and a thermal resistance is also formed between the LED and the circuit board. Due to the thermal resistance between the circuit board and the heatsink lamp holder or the thermal resistance between the LED and the circuit board, the heat energy generated by the LED accumulates and cannot be effectively dissipated through the heatsink lamp holder.

### SUMMARY OF THE INVENTION

The heat energy generated by the LED cannot be effectively dissipated due to the thermal resistance between the circuit board and the heatsink lamp holder or the thermal resistance between the LED and the circuit board. Accordingly, the present invention is a manufacturing method of a light source module and a structure thereof, which can effectively alleviate the thermal resistance problem.

The present invention provides a manufacturing method of a light source module, which comprises the following steps. First, a heatsink substrate is provided, in which the heatsink has a plurality of heatsink fins, and the heatsink substrate and the heatsink fins are integrally formed. Then, a circuit substrate is adhered to the heatsink substrate, in which the circuit substrate has a through hole and two electrodes, and an LED packaging process is directly performed on the circuit substrate. Afterwards, an LED chip is buried in the through hole on the circuit substrate so that the LED chip is in direct contact with the heatsink substrate, and two leads are provided to electrically connect the two electrodes of the circuit substrate and the LED chip. Finally, a packaging material is formed on the LED chip.

The present invention provides a structure of a light source module, which comprises a heatsink substrate, a circuit substrate, an LED chip and a packaging material. The heatsink substrate has a plurality of heatsink fins, and the heatsink substrate and the heatsink fins are integrally formed. The circuit substrate is disposed on the heatsink substrate, and the circuit substrate has at least one through hole and at least two electrodes. The LED chip is buried in the through hole and is in contact with the heatsink substrate, and the LED chip is electrically connected to the two electrodes through at least two leads. The packaging material wraps the LED chip.

According to the manufacturing method of the light source module and the structure thereof provided by the present invention, the LED packaging process and the LED bulb manufacturing process are integrated, so that the LED chip generating heat energy may be in direct contact with the heatsink substrate, and the heat energy of the LED chip can be directly transferred to the heatsink substrate for heat dissipation, thus effectively solving the heat dissipation problem of the LED.

These and other aspects of the present invention will become apparent from the following description of the preferred embodiment taken in conjunction with the following drawings, although variations and modifications therein may be affected without departing from the spirit and scope of the novel concepts of the disclosure.

### BRIEF DESCRIPTION OF THE DRAWINGS

The accompanying drawings illustrate one or more embodiments of the invention and, together with the written description, serve to explain the principles of the invention. Wherever possible, the same reference numbers are used throughout the drawings to refer to the same or like elements of an embodiment, and wherein:

FIG. 1A is a schematic three-dimensional view of a light source module according to an embodiment of the present invention;

FIG. 1B is a schematic enlarged view of FIG. 1A;

FIG. 2 is a schematic sectional view of FIG. 1A;

FIGS. 3A to 3F are schematic views illustrating a packaging process of a light source module according to an embodiment of the present invention; and

FIG. 4 is a flow chart of a packaging process of a light source module according to an embodiment of the present invention.

### DETAILED DESCRIPTION OF THE INVENTION

According to the manufacturing method of the light source module and the structure thereof provided by the present invention, the light source module refers to that an LED is used as a light source, and the specific form thereof may be a bulb type or a lighting tube type, and in the following description, the bulb type is taken as an example.

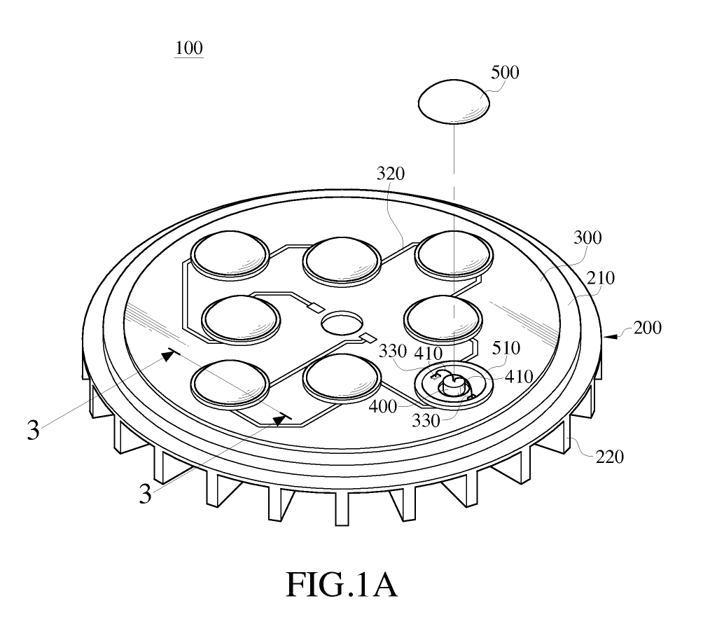

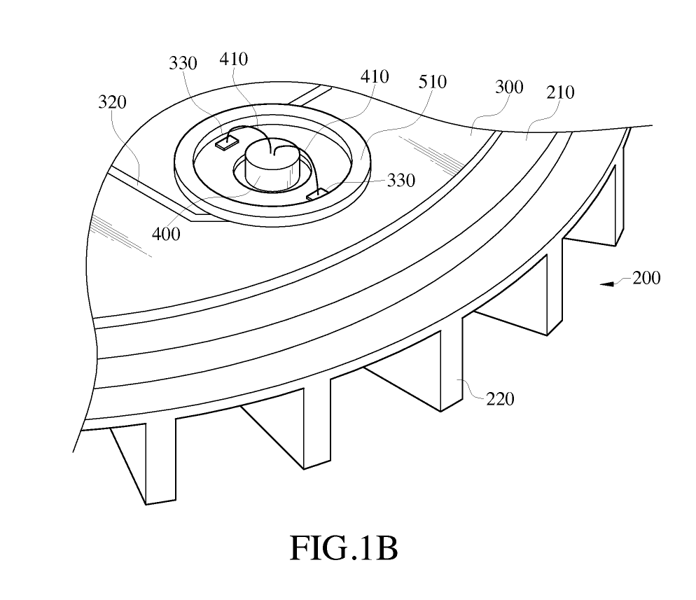

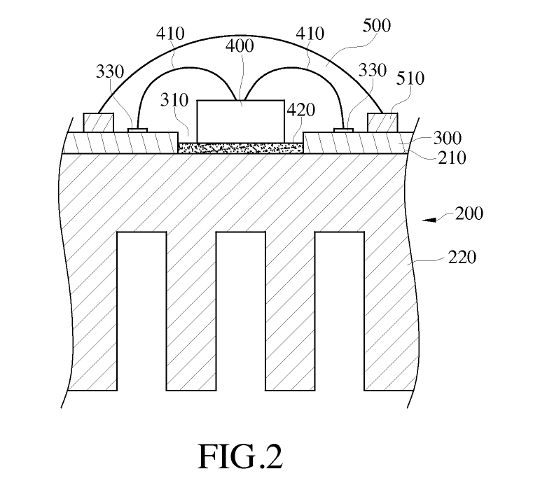

Referring to FIGS. 1A, 1B and 2, FIG. 1A is a schematic three-dimensional view of a light source module 100 according to an embodiment of the present invention, FIG. 1B is a schematic enlarged view of FIG. 1A, and FIG. 2 is a schematic sectional view of FIG. 1A. The structure is first described below, and manufacturing steps and experimental data will be described later. In this embodiment, the light source module 100 comprises a heatsink substrate 200, a circuit substrate 300, an LED chip 400 and a packaging material 500.

The heatsink substrate 200 may be made of a heatsink metal with high thermal conductivity such as an aluminum alloy or a copper alloy, and the heatsink substrate 200 has a contact surface 210 and a plurality of heatsink fins 220 opposite to the contact surface 210. The heatsink fins 220 are for increasing the contact area of the heatsink substrate 200 and the outside, and the heatsink substrate and the heatsink fins are integrally formed. The shape and size of the heatsink substrate 200 are usually designed according to the light source module 100, but the present invention is not limited to this embodiment.

The circuit substrate 300 is adhered to the contact surface 210 of the heatsink substrate 200, and the circuit substrate 300 may be made of a glass fiber board or a flexible circuit board having a thickness of less than 0.15 millimeters. Moreover, the circuit substrate 300 is an insulator, so that the wiring on the circuit substrate 300 is not in direct contact with the heatsink substrate 200, and thus short circuit is avoided. The circuit substrate 300 comprises at least one through hole 310, at least one patterned circuit 320 and at least two electrodes 330. The through hole 310 runs through the circuit substrate 300, so as to expose the contact surface 210 of the heatsink substrate 200. The patterned circuit 320 is disposed on the circuit substrate 300, and the two electrodes 330 are electrically connected to the patterned circuit 320 and is distributed adjacent to the through hole 310.

The LED chip 400 is buried in the through hole 310, and is in direct contact with the heatsink substrate 200 through a thermally conductive adhesive 420. The thermally conductive adhesive 420 may be a silver paste, and is mainly used to fill in a gap between the LED chip 400 and the heatsink substrate 200, so that the heat energy generated by the LED chip 400 can be smoothly conducted to the heatsink substrate 200.

It should be noted that, in the drawings of this embodiment, the thickness of the circuit substrate 300, the electrodes 330, the LED chip 400 and the thermally conductive adhesive 420 is presented in a manner intended to foster ease of understanding by the reader, but the scale of the devices in the drawings is not intended to limit the present invention. For example, in practical applications, the thermally conductive adhesive 420 is located between the LED chip 400 and the heatsink substrate 200, and fills in a tiny gap between the LED chip 400 and the heatsink substrate 200, so as to achieve effective heat transfer. For example, the LED chip 400 may be fully adhered to the heatsink substrate 200, and the thermally conductive adhesive 420 may also not be required.

The packaging material 500 may be light transmissive epoxy, and the packaging material 500 wraps the LED chip 400, two leads 410 and the through hole 310. The packaging material 500 of this embodiment may also contain fluorescent powder (not shown), and in order to enable the LED chip 400 to emit light of different colors, corresponding fluorescent powder (not shown) may be mixed into the packaging material 500.

In this embodiment, the structure further comprises a washer 510, which is disposed on the circuit substrate 300 and frames the through hole 310 and the LED chip 400, so that the packaging material 500 is filled in the washer 510 and wraps the through hole 310, the LED chip 400 and the two leads 410. However, the washer 510 may be a plastic pad, and may also be disposed on the circuit substrate 300 by dispensing.

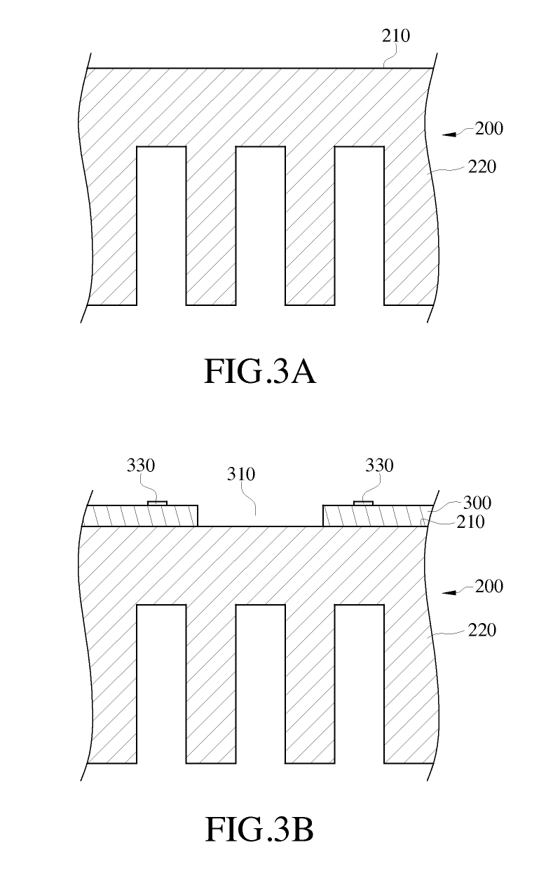

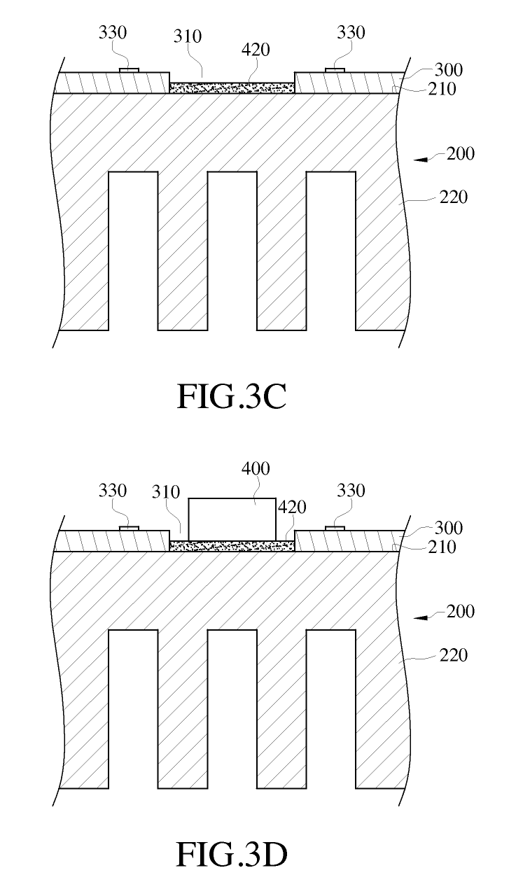

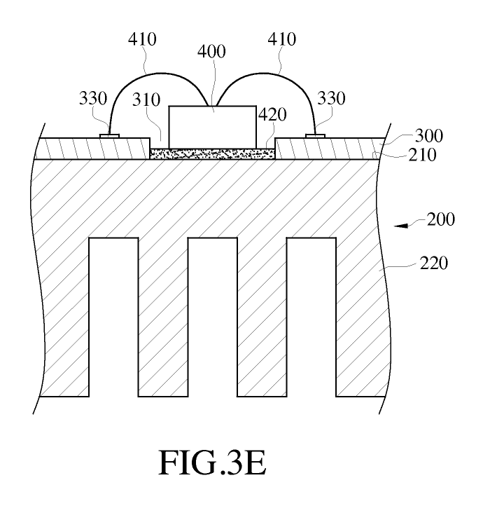

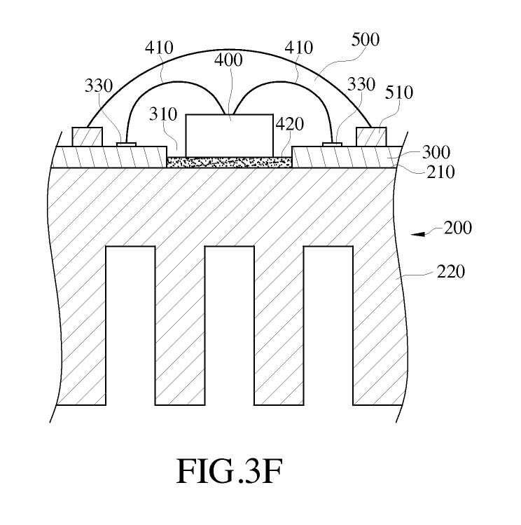

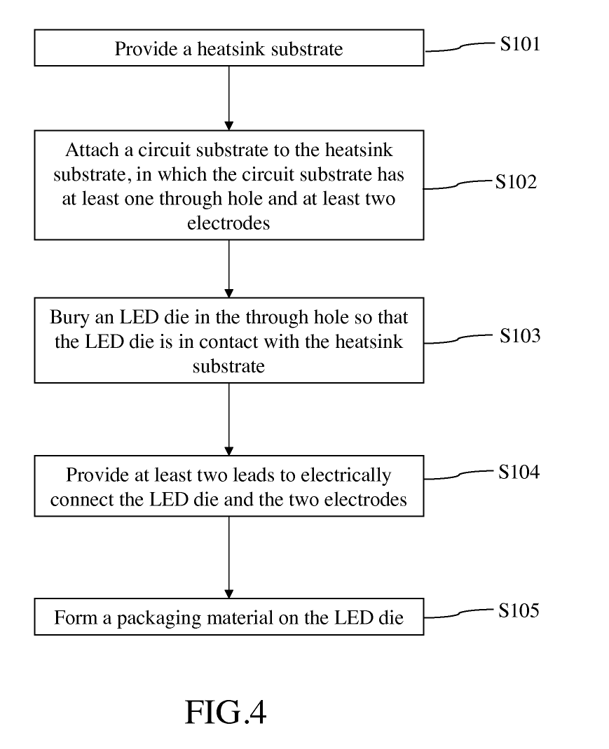

The packaging process of the light source module 100 is described in detail below, and the number of the light source modules 100 is a group for ease of description. Referring to FIGS. 3A to 3F and FIG. 4, FIGS. 3A to 3F are schematic sectional views illustrating a packaging process of a light source module 100 according to an embodiment of the present invention, and FIG. 4 is a flow chart of a packaging process of a light source module 100 according to an embodiment of the present invention, in which the LED packaging process and the LED bulb manufacturing process are integrated.

First, as shown in FIG. 3A, a heatsink substrate 200 is provided, and the heatsink substrate 200 has a contact surface 210 and a plurality of heatsink fins 220 opposite to the contact surface 210 (S101).

Then, as shown in FIG. 3B, a circuit substrate 300 is attached to the contact surface 210 of the heatsink substrate 200, and the circuit substrate 300 has at least one through hole 310 and at least two electrodes (S102). The step of attaching the circuit substrate 300 to the contact surface 210 may be implemented through many methods. For example, one of the methods is to perform anodic treatment on the contact surface 210 first, and then form a patterned circuit 320 and two electrodes 330 on the heatsink substrate 200 by electroplating. The patterned circuit 320 and the two electrodes 330 may be formed on the heatsink substrate 200 by printing, sputtering, laser engraving, lamination or other chemical or physical vapor deposition processes. Another method is to directly adhere the circuit substrate 300 fabricated in advance to the heatsink substrate 200, in which, the thickness of the circuit substrate 300 needs to be less than 0.15 millimeters. Still another method is to form an insulating layer (not shown) by a semiconductor process, and form the through hole 310 and the two electrodes 330 on the insulating layer (not shown).

Afterwards, as shown in FIGS. 3C and 3D, firstly, a thermally conductive adhesive 420 is injected into the through hole 310 by dispensing (as shown in FIG. 3C), and then, an LED chip 400 is buried in the through hole 310 so that the LED chip 400 is in contact with the heatsink substrate 200 (S103). Such a step is also called “chip bond”, which refers to that, another high-temperature baking process may be performed to cure the thermally conductive adhesive 420 at a temperature of about 150° C. after the LED chip 400 is buried.

Afterwards, as shown in FIG. 3E, at least two leads 410 are provided to electrically connect the LED chip 400 and the two electrodes 330 (S104), which is generally called a wire bonding step, and a wire bonder may be used to solder the leads 410 onto the LED chip 400 and the electrodes 330.

Afterwards, as shown in FIG. 3F, a packaging material 500 is formed on the LED chip 400 (S105). The packaging material 500 may be light transmissive epoxy, and the packaging material 500 should have the following properties: (1) desirable adhesion, because the packaging material 500 is usually adhered to a glass interface and a Printed Circuit Board (PCB) interface; (2) low oxygen permeability and water permeability, so as to prevent the oxidation of the LED chip 400; and (3) small coefficient of thermal expansion, so that the packaging material 500 does not easily deform due to heat.

Before the step of forming the packaging material 500 on the LED chip 400, the method further comprises the following steps. First, fluorescent powder (not shown) is mixed into the packaging material 500. Then, a washer 510 is provided to frame the through hole 310 and the LED chip 400, and the washer 510 is adhered to the circuit substrate 300.

The actual effect of the optical module and the packaging process thereof according to this embodiment is proved by the following table.

TABLE
Comparison table of temperatures of LED bulbs in the
present invention and in the prior art

| | Temperature (° C.) in the | Temperature (° C.) |
|---|---|---|
| | present invention | in the prior art |
| LED Top | 82.0 | 90.3 |
| Al Center | 80.9 | 74.4 |
| Heat Sink Top | 78.6 | 72.9 |
| Heat Sink Bottom | 76.5 | 72.2 |

It can be clearly seen from the table that, the temperature of the surface of the LED chip (LED Top) in the present invention is 8° C. lower than that in the prior art. The temperature of the heatsink substrate (comprising Al Center, Heat Sink Top and Heat Sink Bottom) in the present invention is 4° C. to 6° C. higher than that in the prior art. It can be seen from the above that, the heat energy generated by the LED of the present invention can surely be transferred to the heatsink substrate through thermal conduction, and then exchanges heat with external cold air.

According to the manufacturing method of the light source module and the structure thereof provided by the present invention, the LED packaging process and the LED bulb manufacturing process are integrated, so that the LED chip generating heat energy may be in direct contact with the heatsink substrate, and the heat energy of the LED chip can be directly transferred to the heatsink substrate for heat dissipation, thus effectively solving the heat dissipation problem of the LED.

What is claimed is:

1. A manufacturing method of a light source module, comprising:
providing a heatsink substrate, wherein the heatsink substrate has a plurality of heatsink fins, and the heatsink substrate and the heatsink fins are integrally formed;
attaching a circuit substrate to the heatsink substrate, wherein the circuit substrate has at least one through hole and at least two electrodes;
burying a light-emitting diode (LED) chip in the through hole so that the LED chip is in contact with the heatsink substrate;
providing at least two leads to electrically connect the LED chip and the two electrodes; and
forming a packaging material on the LED chip.

2. The manufacturing method of the light source module according to claim 1, wherein the step of attaching the circuit substrate further comprises: adhering the circuit substrate to the heatsink substrate.

3. The manufacturing method of the light source module according to claim 1, wherein the step of attaching the circuit substrate further comprises: forming an insulating layer by a semiconductor process, forming the through hole on the insulating layer, and forming the two electrodes on the insulating layer.

4. The manufacturing method of the light source module according to claim 1, wherein the step of burying the LED chip further comprises: filling in a thermally conductive adhesive between the LED chip and the heatsink substrate.

5. The manufacturing method of the light source module according to claim 1, wherein before the step of forming the packaging material, the method further comprises: mixing fluorescent powder into the packaging material.

6. The manufacturing method of the light source module according to claim 1, wherein before the step of forming the packaging material and after the step of providing the fluorescent powder, the method further comprises: providing a washer to frame the through hole and the LED chip, and adhering the washer to the circuit substrate.

7. A structure of a light source module, comprising:
a heatsink substrate, having a plurality of heatsink fins, wherein the heatsink substrate and the heatsink fins are integrally formed;
a circuit substrate, disposed on the heatsink substrate, and having at least one through hole and at least two electrodes;
a light-emitting diode (LED) chip, buried in the through hole and in contact with the heatsink substrate, wherein the LED chip is electrically connected to the two electrodes through at least two leads; and
a packaging material, wrapping the LED chip.

8. The structure of the light source module according to claim 7, wherein the heatsink substrate is made of an aluminum alloy or a copper alloy.

9. The structure of the light source module according to claim 7, wherein the circuit substrate is a glass fiber board or a flexible circuit board.

10. The structure of the light source module according to claim 7, wherein the thickness of the circuit substrate is less than 0.15 millimeters.

11. The structure of the light source module according to claim 7, wherein a thermally conductive adhesive is provided between the heatsink substrate and the LED chip.

12. The structure of the light source module according to claim 7, wherein the packaging material further contains fluorescent powder, so that the LED chip emits light of a certain color.

13. The structure of the light source module according to claim 7, further comprising: a washer, disposed on the circuit substrate, and framing the through hole and the LED chip, so that the packaging material is filled in the washer and wraps the through hole, the LED chip and the leads.
